(19) United States
(12) Patent Application Publication
(10) Pub. No.: US 2015/0115955 A1
(43) Pub. Date: Apr. 30, 2015

(54) SYSTEMS AND METHODS FOR ACCELERATING MAGNETIC RESONANCE IMAGING

(71) Applicant: General Electric Company, Schenectady, NY (US)

(72) Inventors: Seung-Kyun Lee, Cohoes, NY (US); Christopher Judson Hardy, Schenectady, NY (US); Ek Tsoon Tan, Mechanicville, NY (US)

(73) Assignee: General Electric Company, Schenectady, NY (US)

(21) Appl. No.: 14/067,701

(22) Filed: Oct. 30, 2013

(51) Int. Cl. G01R 33/561

(52) U.S. Cl. CPC G01R 33/561
USPC 324/309; 324/322

(57) ABSTRACT

Magnetic resonance imaging systems and methods are provided. A method includes applying a slice selection gradient perpendicular to a desired slice plane and applying, substantially simultaneously with the slice selection gradient, a radiofrequency nuclear magnetic resonance excitation pulse having a bandwidth corresponding to the desired slice plane and a frequency corresponding to the frequency of protons present in the desired slice plane. The method also includes applying, during an encoding period and in a first direction, a phase encoding gradient having a phase encoding portion and a shearing portion and applying, during the readout period and in a second direction perpendicular to the first direction, a frequency encoding gradient having a portion having substantially the same shape as the shearing portion of the phase encoding gradient.

### BACKGROUND

The subject matter disclosed herein relates generally to magnetic resonance imaging (MRI) systems and methods and, more particularly, to systems and methods for accelerating image acquisition sequences in MRI.

In general, magnetic resonance imaging (MRI) examinations are based on the interactions among a primary magnetic field, a radiofrequency (RF) magnetic field and time varying magnetic gradient fields with gyromagnetic material having nuclear spins within a subject of interest, such as a patient. Certain gyromagnetic materials, such as hydrogen nuclei in water molecules, have characteristic behaviors in response to external magnetic fields. The precession of spins of these nuclei can be influenced by manipulation of the fields to produce RF signals that can be detected, processed, and used to reconstruct a useful image.

Depending on the application, MRI may be performed as a two or three dimensional type of imaging operation. In traditional three dimensional imaging, different image slices of the subject are separated by using a magnetic gradient for slice selection or phase encoding. The length of time necessary for the image acquisition is proportional to the number of desired slices. Similarly, in two dimensional imaging, lines parallel to the readout direction are separated by phase encoding, and the number of phase encoding steps determines the total image acquisition time. In this way, image acquisition time is traditionally dependent on the number of phase and/or slice encoding steps.

In many instances, it is desirable to quickly obtain images of the subject without sacrificing diagnostically useful information that may be included in the chosen slices of the subject. Faster image acquisition may enable benefits such as artifact reduction (e.g., due to reduced movement of the subject), high temporal resolution, increased throughput at imaging sites, and so forth. However, acceleration of the imaging acquisition via reduction of the number of imaged slices of the subject may lead to a reduction in the quantity or quality of diagnostically useful information. Accordingly, there exists a need for improved systems and methods that address the need for diagnostically rich and fast imaging acquisition in MRI.

### BRIEF DESCRIPTION

In one embodiment, a method includes applying a slice selection gradient perpendicular to a desired slice plane and applying, substantially simultaneously with the slice selection gradient, a nuclear magnetic resonance (NMR) excitation pulse having a bandwidth corresponding to the desired slice plane and a frequency corresponding to the frequency of protons present in the desired slice plane. The method also includes applying, during an encoding period and in a first direction, a phase encoding gradient having a phase encoding portion and a shearing portion and applying, during the readout period and in a second direction perpendicular to the first direction, a frequency encoding gradient having a portion having substantially the same shape as the shearing portion of the phase encoding gradient. Here, the slice selection gradient, the phase encoding gradient, and the frequency encoding gradients refer to three orthogonal combinations of the physical gradient axes present in the MRI system.

In another embodiment, a magnetic resonance system includes a first gradient coil controllable to produce a phase encoding gradient having a phase encoding step portion and a shearing portion and to apply the phase encoding gradient to a subject in a first direction. The system also includes a second gradient coil controllable to produce a frequency encoding gradient having a portion having substantially the same shape as the shearing portion of the phase encoding gradient, and to apply the frequency encoding gradient to the subject in a second direction perpendicular to the first direction. A controller is adapted to control the first gradient coil to produce the phase encoding gradient and the second gradient coil to produce the frequency encoding gradient during a readout period when a signal produced from an interrogation region of the subject is detected.

In another embodiment, a magnetic resonance imaging method includes receiving a plurality of signals each obtained during a phase encoding step of a magnetic resonance data acquisition operation having an encoding period during which a phase encoding gradient and a frequency encoding gradient, each having a shearing portion of substantially the same shape and different strengths, are concurrently applied to an imaged subject. The method also includes processing the plurality of signals to reconstruct a sheared image of the imaged subject and to unshear the sheared image to generate a reconstructed, unsheared image of the imaged subject.

In another embodiment, non-transitory computer readable medium encoding one or more executable routines, which, when executed by a processor, causes the processor to perform acts including controlling a first gradient coil to apply a slice selection gradient perpendicular to a desired slice plane; controlling a radiofrequency coil to apply, substantially simultaneously with the slice selection gradient, a radiofrequency wave having a bandwidth corresponding to the desired slice plane and a frequency corresponding to the frequency of protons present in the desired slice plane; controlling a second gradient coil to apply, during an encoding period and in a first direction, a phase encoding gradient comprising a phase encoding portion and a shearing portion; and controlling a third gradient coil to apply, during the readout period and in a second direction perpendicular to the first direction, a frequency encoding gradient comprising a portion having substantially the same shape as the shearing portion of the phase encoding gradient.

### BRIEF DESCRIPTION OF THE DRAWINGS

These and other features, aspects, and advantages of the present invention will become better understood when the following detailed description is read with reference to the accompanying drawings in which like characters represent like parts throughout the drawings, wherein:

FIG. 1 is a diagrammatical illustration of an embodiment of a magnetic resonance (MR) imaging system configured to acquire MR images in accordance with an aspect of the present disclosure;

FIG. 2 is a flow chart illustrating an embodiment of a method for accelerating data acquisition through oblique viewing in an MRI operation;

FIGS. 3A-C schematically illustrate an embodiment of a two dimensional accelerated imaging method;

FIG. 4 illustrates an embodiment of a pulse sequence that may be utilized to implement the accelerated imaging method of FIGS. 3A-C; and

FIGS. 5A-F illustrate an embodiment of an accelerated imaging method through an MRI simulation.

### DETAILED DESCRIPTION

As described in more detail below, provided herein are systems and methods for performing accelerated imaging of a subject (e.g., a patient or object) using magnetic resonance imaging (MRI) systems. More specifically, various embodiments provided herein may enable a reduction in image acquisition time by an acceleration factor of N by performing only every N^{th} phase encoding step and subsequently resolving the resulting N-fold aliasing via oblique viewing during readout. In some embodiments, an acceleration factor of N=2 or N=3 may be realized. Additionally, in certain embodiments, the acceleration factor may be further improved by combining the acceleration methods disclosed herein with parallel imaging. The foregoing features may enable a substantial reduction in imaging time in both two dimensional and three dimensional scans by reducing the number of phase or slice encoding steps without introducing aliasing and without reducing the presence of information in the reconstructed images. These and other features of presently disclosed embodiments are described in more detail below.

The implementations described herein may be performed by a magnetic resonance imaging (MRI) system, wherein specific imaging routines are initiated by a user (e.g., a radiologist). For example, the implementations described herein may be applicable to a variety of types of acquisition schemes known to those skilled in the art. For further example, the disclosed embodiments may be utilized with two or three dimensional MRI applications.

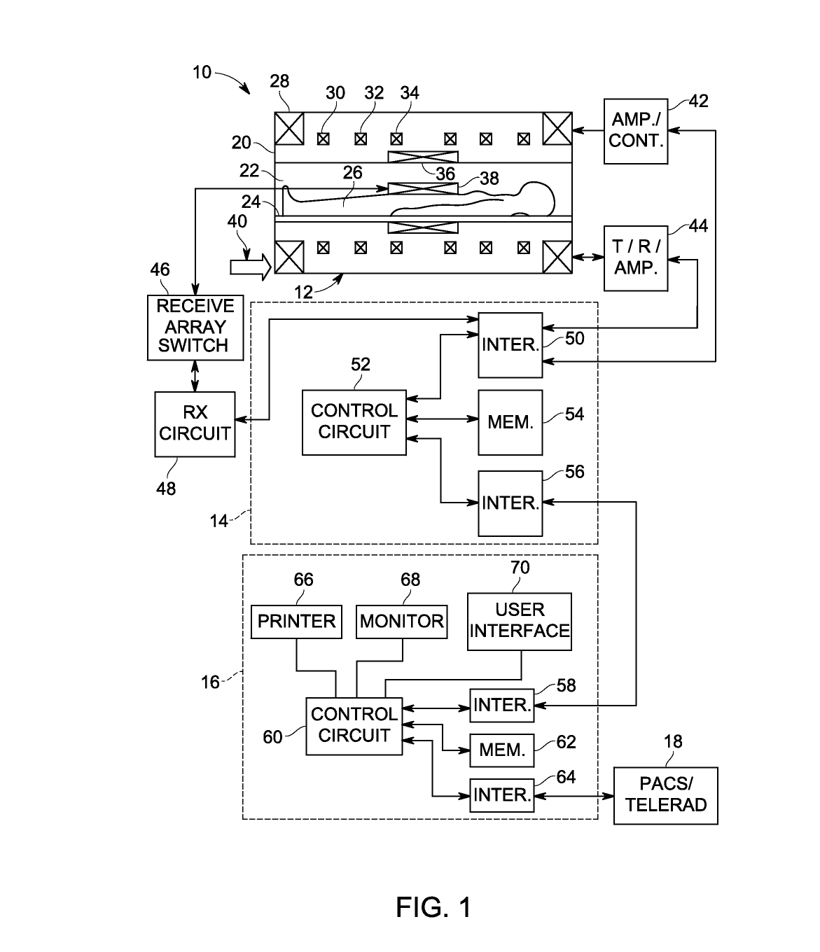

Further, the MRI system may perform data acquisition, data construction, image reconstruction/synthesis, and image processing. Accordingly, referring to FIG. 1, a magnetic resonance imaging system 10 is illustrated schematically as including a scanner 12, a scanner control circuit 14, and a system control circuitry 16. System 10 additionally includes remote access and storage systems or devices as picture archiving and communication systems (PACS) 18, or other devices, such as teleradiology equipment, so that data acquired by the system 10 may be accessed on-site or off-site. While the MRI system 10 may include any suitable scanner or detector, in the illustrated embodiment, the system 10 includes a full body scanner 12 having a housing 20 through which a bore 22 is formed. A table 24 is moveable into the bore 22 to permit a patient 26 to be positioned therein for imaging selected anatomy within the patient 26. The selected anatomy may be imaged by a combination of patient positioning, selected excitation of certain gyromagnetic nuclei within the patient 26, and by using certain features for receiving data from the excited nuclei as they spin and precess, as described below.

Scanner 12 includes a series of associated coils for producing controlled magnetic fields for exciting the gyromagnetic material within the anatomy of the subject being imaged. Specifically, a primary magnet coil 28 is provided for generating a primary magnetic field generally aligned with the bore 22. A series of gradient coils 30, 32, and 34 permit controlled magnetic gradient fields to be generated for positional encoding of certain of the gyromagnetic nuclei within the patient 26 during examination sequences. A radio frequency (RF) coil 36 is provided, and is configured to generate radio frequency pulses for exciting the certain gyromagnetic nuclei within the patient. In addition to the coils that may be local to the scanner 12, the system 10 also includes a set of receiving coils 38 (e.g., a phased array of coils) configured for placement proximal to (e.g., against) the patient 26. The receiving coils 38 may have any geometry, including both enclosed and single-sided geometries.

As an example, the receiving coils 38 can include cervical/thoracic/lumbar (CTL) coils, head coils, single-sided spine coils, and so forth. Generally, the receiving coils 38 are placed close to or on top of the patient 26 so as to receive the weak RF signals (weak relative to the transmitted pulses generated by the scanner coils) that are generated by certain of the gyromagnetic nuclei within the patient 26 as they return to their relaxed state. The receiving coils 38 may be switched off so as not to receive or resonate with the transmit pulses generated by the scanner coils, and may be switched on so as to receive or resonate with the RF signals generated by the relaxing gyromagnetic nuclei.

The various coils of system 10 are controlled by external circuitry to generate the desired field and pulses, and to read emissions from the gyromagnetic material in a controlled manner. For example, in certain embodiments of the accelerated imaging methods described herein, first and second gradient coils may be controlled to apply a frequency encoding gradient and a phase encoding gradient, respectively, substantially simultaneously during a readout period of the imaging acquisition. Each of the frequency and phase encoding gradients may include a shearing portion having substantially the same shape but with different strengths, thus resulting in an image sheared in the readout direction. This may enable every other phase encoding step to be eliminated, thus reducing the phase field of view and imaging time by a factor of 2, while still enabling recovery of an unsheared image since the amount of shearing in the reconstructed image is predetermined by the relative strengths of the shearing portions of the frequency and phase encoding gradients.

In the illustrated embodiment, a main power supply 40 provides power to the primary field coil 28. In certain embodiments, if the primary field coil 28 is a superconducting magnet operated in its persistent current mode, the power supply 40 is used for initial magnetic field ramp-up only. A driver circuit 42 is provided for pulsing the gradient field coils 30, 32, and 34. Such a circuit may include amplification and control circuitry for supplying current to the coils as defined by digitized pulse sequences output by the scanner control circuit 14. Another control circuit 44 is provided for regulating operation of the RF coil 36. Circuit 44 includes a switching device for alternating between the active and inactive modes of operation, wherein the RF coil 36 transmits and does not transmit signals, respectively. Circuit 44 also includes amplification circuitry for generating the RF pulses. Similarly, the receiving coils 38 are connected to switch 46 that is capable of switching the receiving coils 38 between receiving and non-receiving modes such that the receiving coils 38 resonate with the RF signals produced by relaxing gyromagnetic nuclei from within the patient 26 while in the receiving state, and they do not resonate with RF energy from the transmitting coils (i.e., coil 36) so as to prevent undesirable operation while in the non-receiving state. Additionally, a receiving circuit 48 is provided for receiving the data detected by the receiving coils 38, and may include one or more multiplexing and/or amplification circuits.

In the illustrated embodiment, scanner control circuit 14 includes an interface circuit 50 for outputting signals for driving the gradient field coils 30, 32, 34 and the RF coil 36. Additionally, interface circuit 50 receives the data representative of the magnetic resonance signals produced in examination sequences from the receiving circuitry 48 and/or the receiving coils 38. The interface circuit 50 is operatively connected to a control circuit 52. The control circuit 52 executes the commands for driving the circuit 42 and circuit 44 based on defined protocols selected via system control circuit 16. Control circuit 52 also serves to provide timing signals to the switch 46 so as to synchronize the transmission and reception of RF energy. Further, control circuit 52 receives the magnetic resonance signals and may perform subsequent processing before transmitting the data to system control circuit 16. Scanner control circuit 14 also includes one or more memory circuits 54, which store configuration parameters, pulse sequence descriptions, examination results, and so forth, during operation. The memory circuits 54, in certain embodiments, may store instructions for implementing at least a portion of the image processing techniques described herein.

Interface circuit 56 is coupled to the control circuit 52 for exchanging data between scanner control circuit 14 and system control circuit 16. Such data may include selection of specific examination sequences to be performed, configuration parameters of these sequences, and acquired data, which may be transmitted in raw or processed form from scanner control circuit 14 for subsequent processing, storage, transmission and display.

An interface circuit 58 of the system control circuit 16 receives data from the scanner control circuit 14 and transmits data and commands back to the scanner control circuit 14. The interface circuit 58 is coupled to a control circuit 60, which may include one or more processing circuits in a multi-purpose or application specific computer or workstation. Control circuit 60 is coupled to a memory circuit 62, which stores programming code for operation of the MRI system 10 and, in some configurations, the image data for later reconstruction, display and transmission. An additional interface circuit 64 may be provided for exchanging image data, configuration parameters, and so forth with external system components such as remote access and storage devices 18. Finally, the system control circuit 60 may include various peripheral devices for facilitating operator interface and for producing hard copies of the reconstructed images. In the illustrated embodiment, these peripherals include a printer 66, a monitor 68, and user interface 70 including devices such as a keyboard or a mouse.

It should be noted that subsequent to the acquisitions described herein, the system 10 may simply store the acquired data for later access locally and/or remotely, for example in a memory circuit (e.g., memory 56, 62). Thus, when accessed locally and/or remotely, the acquired data may be manipulated by one or more processors contained within an application-specific or general-purpose computer. The one or more processors may access the acquired data and execute routines stored on one or more non-transitory, machine readable media collectively storing instructions for performing methods including the image processing, correction, and reconstruction methods described herein.

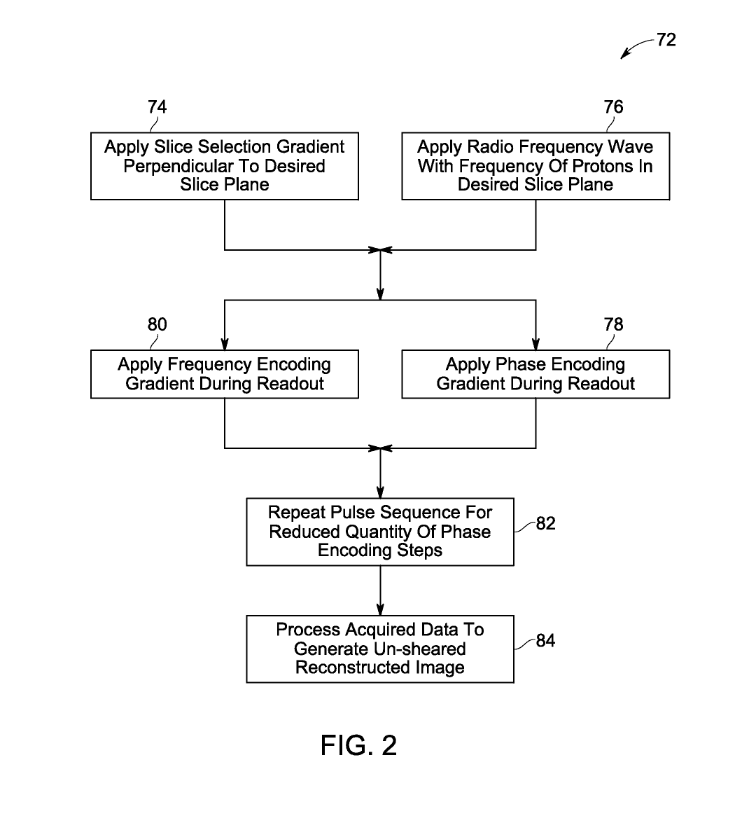

Further, it should be noted that the MRI system 10 may be utilized to implement a variety of accelerated imaging acquisition schemes and to correct the acquired MR data to produce a reconstructed, unsheared image in accordance with the embodiments described herein. For example, the MRI system 10 of FIG. 1 may be utilized to implement the accelerated data acquisition method 72 illustrated in FIG. 2. In the illustrated method 72, a slice selection gradient (e.g., G_{z}) is applied perpendicular to the desired slice plane at an amplitude corresponding to the desired slice through the subject (block 74). Substantially simultaneously (operational variations may occur due to system operation, component coordination delays, etc.), the radiofrequency (RF) coil is utilized to apply an RF wave having the same frequency as that of the protons in the desired slice plane and a bandwidth that corresponds to the desired slice plane (block 76). Taken together, the slice selection gradient and the RF wave enable an imaging slice to be selected for the first step of the imaging operation. In certain embodiments, the nuclear magnetic resonance (NMR) excitation pulse may take an alternative form, not limited to an RF wave.

Subsequently, a phase encoding gradient (e.g., G_{y}) is applied during readout (block 78) concurrent with a frequency encoding gradient (e.g., Gₓ) also applied during readout (block 80). As described in more detail below, the phase encoding gradient includes a phase encoding portion, which defines a phase encoding step, and a shearing portion, which, along with a shearing portion of the frequency encoding gradient, defines an amount of shearing or viewing angle tilt achieved during the imaging of the given slice. The frequency encoding gradient also includes a shearing portion having substantially the same shape as the shearing portion of the phase encoding gradient but with a different strength. The ratio between the strengths of the shearing portions determines the amount of shearing in the acquired image and can thus be used to generate an unsheared image.

This feature enables acquisition of image data with a reduced number of phase encoding steps but without the introduction of aliasing. Accordingly, the method 72 also includes repeating the pulse sequence for a reduced quantity of phase encoding steps (block 82). Once acquired, the reduced dataset may be processed to generate an unsheared, reconstructed image of the imaged subject (block 84). In this way, all the desired pixels may be captured with a reduction in the number of phase encoding steps by increasing the readout field of view. The latter can be achieved by increasing the readout RF bandwidth. In this manner, image acquisition is accelerated without sacrificing data points.

The steps of this method can be described mathematically for both two dimensional (2D) and three dimensional (3D) imaging. There are two types of 3D imaging methods used in MRI. The first one is 3D imaging by collection of multiple 2D slice images, and the second one is 3D imaging through additional phase encoding in the slice direction. In the following, we consider both of the 3D imaging types as well as a single-slice 2D imaging. First, for 3D imaging of multi-slice type, suppose that the proton density in two separate slices, with distance h=z₂−z₁, is given by

ρ₁(x,y)δ(z−z₁);and (1)

ρ₂(x,y)δ(z−z₂). (2)

After RF excitation of both slices, image encoding (ignoring relaxation) with a k-space vector \vec{k}=(kₓ, k_{y}, k_{z}) yields an MR signal given by:

$$S ( {k}^{->} ) = \int \int \int d x d y d z [ {ρ}_{1} ( x , y ) δ ( z - {z}_{1} ) + {ρ}_{2} ( x , y ) δ ( z - {z}_{2} ) ] exp ( i {xk}_{x} + i {yk}_{y} + i z {k}_{z} ) = \int \int d x d y [ {ρ}_{1} ( x , y ) exp ( i {xk}_{x} + i {yk}_{y} + i z {k}_{z} ) + {ρ}_{2} ( x , y ) exp ( i {xk}_{x} + i {yk}_{y} + i {z}_{2} {k}_{z} ) ] . \qquad ( 3 )$$

Now assume that k_{z}=αkₓ+βk_{y}. This can be realized if, whenever the phase (G_{y}) (or readout (Gₓ)) gradient is applied, a slice-gradient (G_{z}) is also applied such that G_{z}=αGₓ+βG_{y}. Then,

S(\vec{k})=S(kₓ,k_{y})=∫∫dxdyexp(ixkₓ+iyk_{y})[ρ₁(x,y)exp(iαz₁kₓ+iβz₁k_{y})+ρ₂(x,y)exp(iαz₂kₓ+iβz₂k_{y})] (4)

where FT [; ,] is the 2D Fourier Transform of the first argument evaluated at the second and third arguments. According to the properties of the Fourier transform, (FT of a function of \vec{r}) multiplied by a plane wave exp (i\vec{k}·\vec{r}₀) is the same as (FT of a function of \vec{r} shifted by −\vec{r}₀). Therefore, the above expression becomes

FT[ρ₁(x−αz₁,y−βz₁);kₓ,k_{y}]+FT[ρ₂(x−αz₂,y−βz₂);kₓ,k_{y}]. (5)

This shows that by turning on the z gradient during within-slice image encoding, one can laterally shift each of the multiple slices by an amount proportional to the slice's z coordinate, in the direction given by the coefficients defining the magnitude of the applied z gradient in relation to the x and y gradients.

This slice shifting can also be performed in 3D imaging of the additional phase encoding type. Consider a 3D spin density in an excited slab (−L/2<z<L/2) given by

ρ₁(x,y,z). (6)

The MR signal at a phase-encoding coordinate (k_{y},k_{z}) and along a readout coordinate kₓ is given by its 3D Fourier transform:

S(\vec{k})=∫∫∫dxdydzρ₁(x,y,z)exp(ixkₓ+iyk_{y}+izk_{z}). (7)

Suppose now that when applying an in-plane encoding gradient (Gₓ or G_{y}), slice encoding gradient is also applied simultaneously such that G_{z}=αGₓ+βG_{y}. This z-gradient is separate from the usual z-gradient necessary for 3D slice encoding. If this is done, the MR signal above contains an additional z-directional spin warp factor

exp(iαzkₓ+iβzk_{y}), (8)

which represents phase winding that occurred during the Gₓ or G_{y} gradient lobes.

Now one can rearrange the integral order of the triple integral to get the following:

S(\vec{k})=∫dzexp(izk_{z})[exp(iαzkₓ+iβzk_{y})∫∫dxdyρ₁(x,y,z)exp(ixkₓ+iyk_{y})]. (9)

The term in the bracket is a function of z, and it is a 2D Fourier transformation (double integral over x and y) multiplied by a plane wave. Therefore, it can be rewritten as a 2D Fourier transformation of a laterally shifted spin density

[ ]=∫∫dxdyρ₁(x−αz,y−βz,z)exp(ixkₓ+iyk_{y}). (10)

By inserting equation 10 into equation 9, one can see that the signal S(\vec{k}) is a 3D Fourier transformation of the shifted spin density

ρ₁(x−αz,y−βz,z). (11)

The resulting 3D image will therefore show the usual slice images ρ₁(x, y, z₁), ρ₁(x, y, z₂), ρ₁(x, y, z₃), . . . altered by slice-dependent lateral shifts:

ρ₁(x−αz₁,y−βz₁,z₁),ρ₁(x−αz₂,y−βz₂,z₂),ρ₁(x−αz₃,y−βz₃,z₃), (12)

Since the amount of shift is known, one can undo the shift and get back the original spin density.

The usefulness of this approach is the following: If a second slab ρ₂ (x, y, z), −3L/2<z<−L/2 had been next to the first slab, then the z-encoding steps should normally be doubled to resolve the two slabs. That will require twice as much time. However, if one does a lateral shift as above and chooses the shift amount per slice as δz\sqrt{α²+β²}=(FOV)/N, where δz is the slice thickness, FOV is the in-plane field of view, and N is the number of slices, then the aliasing of slices is removed pair-wise. In other words, without shift, each slice image will be in fact a sum of slices at z and z+L. With shift, overlap will be resolved since the z slice and the (z+L) slice will appear laterally shifted by FOV. Therefore, the shift technique enables one to image in 3D with half the number of slice phase encoding steps. If one applies shift operation in the readout direction with increased receive bandwidth, then there is no time penalty to cover larger field of view for shifted imaging. In such a case, one can image two slabs in a time corresponding to imaging one slab, speeding up 3D imaging by a factor of two. Part of the phase encoding burden is effectively shifted to increased samplings in the readout encoding.

It should be noted that this analysis can be generalized to a 2D imaging application as well. The same argument can be applied to a 2D single slice imaging procedure. Consider a slice (e.g., axial abdominal slice) with a phase-direction field of view F_{y} (which usually goes along the left-right direction) and readout-direction field of view Fₓ. Phase-encoding direction can often be longer than the readout direction, and high resolution in that direction requires sufficiently many k_{y} encoding steps. Now suppose one samples k_{y} only at half the density. This will create aliasing of pixels on a line at y and a line at (y+F_{y}/2). Now suppose that when one does readout, in addition to the Gₓ, one applies G_{y} too, effectively “projecting” the object at an angle arctan(G_{y}/Gₓ). Then the MR reconstruction will give an image that is a sheared version of the original. If the shear amount is chosen such that pixels separated in y by F_{y}/2 relatively move apart along the x direction by Fₓ, then aliasing in the y-direction does not result in overlap. One can therefore recover all pixels in the slice with half the phase encoding steps. Again, if the readout bandwidth allows increased sampling rate during readout, time may be saved by the same factor. In this manner, MRI data acquisition may be accelerated, thus resulting in decreased data acquisition times.

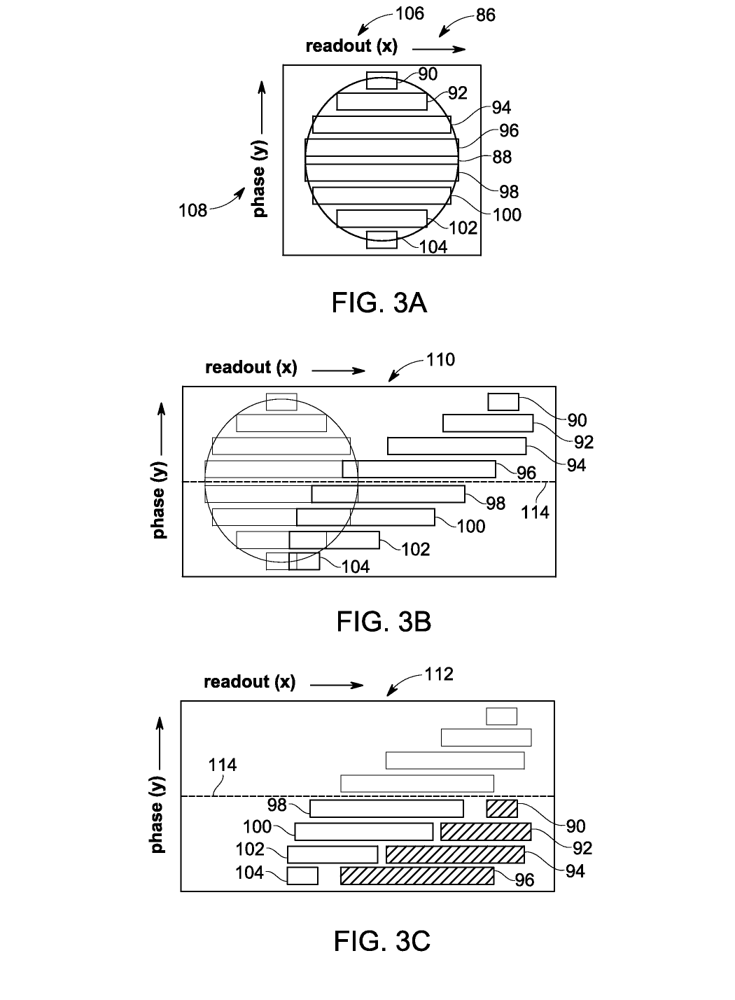

FIGS. 3A-C schematically illustrate an example of the accelerated imaging method for a two dimensional imaging operation. More specifically, FIG. 3A is a schematic 86 illustrating a subject 88 to be imaged. A plurality of rectangles 90, 92, 94, 96, 98, 100, 102, and 104 represent an array of pixels arranged in a readout direction 106 and along a phase direction 108. In a first step, the image is sheared in the readout direction 106 such that the rectangles 90, 92, 94, 96, 98, 100, 102, and 104 shift to the right, as illustrated in the schematic 110 of FIG. 3B. This is accomplished during implementation by applying the frequency encoding gradient (e.g., Gₓ) and the phase encoding gradient (e.g., G_{y}) during the readout period. During imaging acquisition, this enables every other phase encoding step to be eliminated, thus reducing the phase field of view and imaging time by a factor of two.

As shown in the schematic 112 of FIG. 3C, this step effectively translates the upper rectangles 90, 92, 94, and 96 lying above the midline 114 into the lower half of the plane. In traditional imaging, this step would result in undesirable aliasing. However, by applying the presently disclosed shearing method, the two imaged halves don't overlap. Further, since the amount of shearing is predetermined by the relative strengths of Gₓ and G_{y}, an unsheared image may be recovered during post-imaging processing.

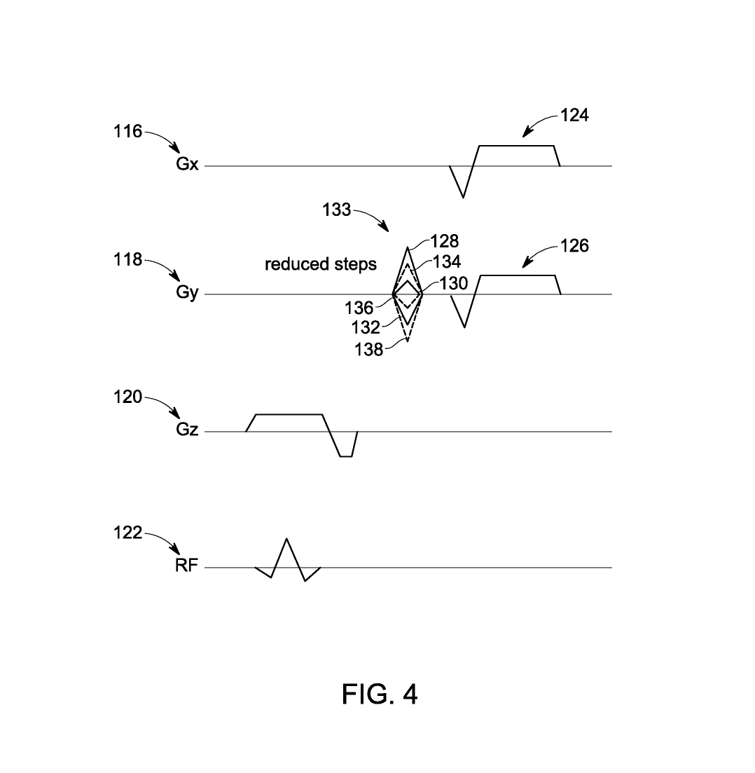

FIG. 4 illustrates an example pulse sequence diagram having a frequency encoding gradient (Gx) 116, a phase encoding gradient (G_{y}) 118, a slice selection gradient (G_{z}), and a radiofrequency (RF) wave 122. However, it should be noted that a variety of pulse sequence diagrams may be suitable for carrying out the accelerated imaging acquisition disclosed herein, not limited to the diagram illustrated in FIG. 4. In the illustrated pulse sequence diagram, the slice selection gradient (G_{z}) and the RF wave 122 are utilized to select the slices of the subject to be imaged.

Further, in the illustrated embodiment, the frequency encoding gradient 116 includes a shearing portion 124 having substantially the same shape as a shearing portion 126 of the phase encoding gradient 118, but a different amplitude. When both the frequency and phase encoding gradients 116 and 118 are applied during the readout period, the ratio of the amplitudes of the shearing portions 124 and 126 defines the amount of shearing in the resulting image. By applying G_{y} along with Gₓ during the readout period, the viewing angle is effectively tilted, thus eliminating undesirable line overlap. Further, a reduction in the number of image acquisition steps may be realized by performing phase encoding steps 128, 130, and 132 in the phase encoding portion 133 of G_{y}, but not performing phase encoding steps 134, 136, and 138. That is, a reduced number of phase encoding steps may be performed without introducing aliasing and without loss of information.

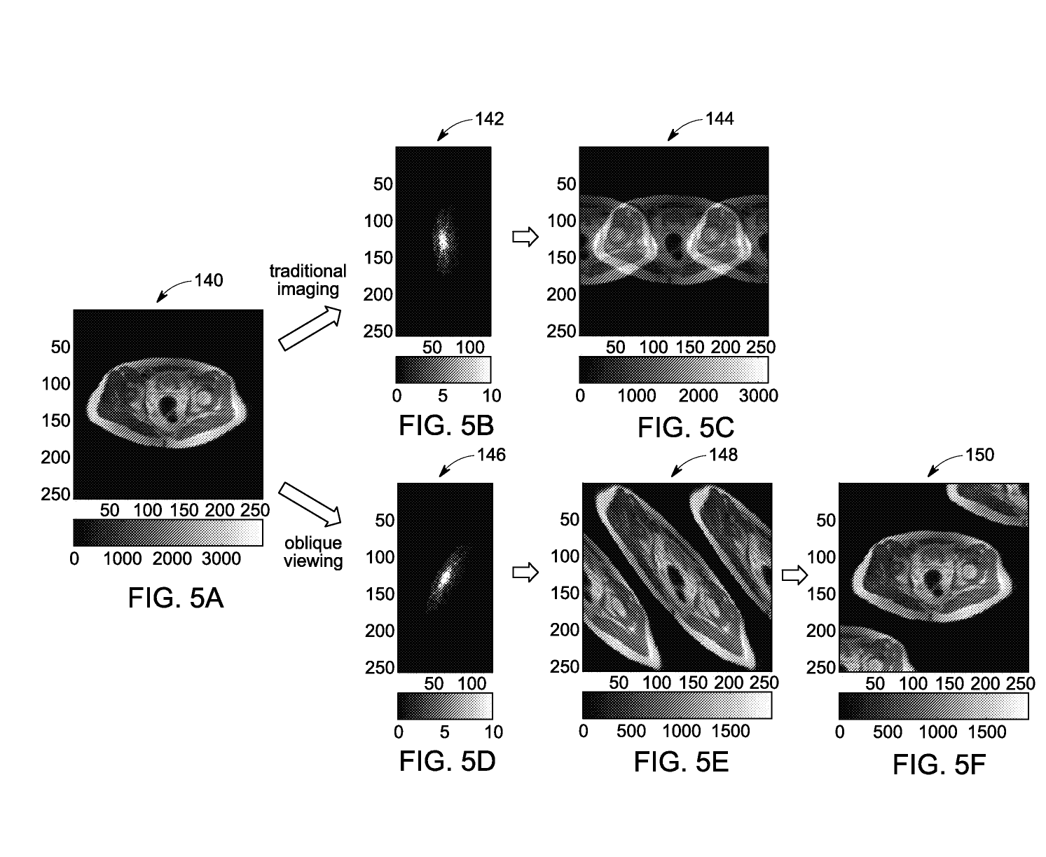

FIGS. 5A-F illustrate an example of the accelerated imaging method generated through a MRI simulation and show restoration of a complete image through oblique viewing from a k-space undersampled by a factor of two. Specifically, FIG. SA illustrates the true object 140. FIG. 5B and FIG. SC illustrate the k-space 142 and the reconstructed image 144, respectively, obtained when utilizing a traditional imaging approach that does not employ shearing. As shown in the reconstructed image 144, aliasing occurs, thus leading to undesirable artifacts in the reconstructed image 144.

FIGS. 5D-F illustrate the benefits of an embodiment of the accelerated imaging method disclosed herein that utilizes oblique viewing to obtain images without aliasing. FIG. SD shows the k-space 146 for the oblique viewing approach, and FIG. SE shows the reconstructed image 148. In this approach, after skew correction, an unaliased image 150 may be obtained as shown in FIG. SF. Again, the unaliased reconstructed image 150 may be obtained with a reduced number of phase encoding steps, thus reducing overall image acquisition time.

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal languages of the claims.

1. A magnetic resonance (MR) imaging method, comprising:
applying a slice selection gradient perpendicular to a desired slice plane;
applying a radiofrequency nuclear magnetic resonance excitation pulse having a bandwidth corresponding to the desired slice plane and a frequency corresponding to the frequency of protons present in the desired slice plane;
applying, during an encoding period and in a first direction, a phase encoding gradient comprising a phase encoding portion and a shearing portion; and
applying, during the readout period and in a second direction perpendicular to the first direction, a frequency encoding gradient comprising a portion having substantially the same shape as the shearing portion of the phase encoding gradient.

2. The method of claim 1, wherein the portion of the frequency encoding gradient and the shearing portion of the phase encoding gradient have different amplitudes, and the difference and/or ratio between the different amplitudes determines a shearing amount.

3. The method of claim 1, comprising processing MR data obtained to generate an unsheared, reconstructed image of an imaged subject.

4. The method of claim 3, wherein processing the MR data comprises determining the amount of shearing by comparing the relative strengths of the phase encoding gradient and the frequency encoding gradient.

5. The method of claim 1, wherein the first direction comprises a vertical direction and the second direction comprises a horizontal direction.

6. A magnetic resonance (MR) system, comprising:
a first gradient coil configured to produce a phase encoding gradient and to apply the phase encoding gradient to a subject in a first direction;
a second gradient coil configured to produce a frequency encoding gradient and to apply the frequency encoding gradient to the subject in a second direction perpendicular to the first direction; and
a controller configured to control the first gradient coil to produce the phase encoding gradient having a phase encoding step portion and a shearing portion, and to control the second gradient coil to produce the frequency encoding gradient having a portion having substantially the same shape as the shearing portion of the phase encoding gradient during a readout period when a signal produced from an interrogation region of the subject is detected.

7. The system of claim 6, wherein the controller is configured to control a first amplitude of the shearing portion and a second amplitude of the portion such that the difference and/or ratio between the first and second amplitudes corresponds to a desired amount of shearing.

8. The system of claim 6, comprising a third gradient coil configured to be controlled to produce a slice selection gradient and to apply the slice selection gradient perpendicular to a desired slice plane of the subject.

9. The system of claim 8, comprising a radiofrequency coil configured to be controlled to produce a radiofrequency wave and to apply the radiofrequency wave to the subject substantially simultaneously with the slice selection gradient.

10. The system of claim 9, wherein the controller is configured to control the bandwidth of the radiofrequency wave to control the width of the desired slice plane.

11. The system of claim 6, wherein the first direction comprises a vertical direction and the second direction comprises a horizontal direction.

12. The system of claim 6, wherein the controller is configured to process the signal obtained from multiple phase encoding steps to produce an unsheared reconstructed image of the interrogation region of the subject.

13. A magnetic resonance (MR) imaging method, comprising:
receiving a plurality of signals each obtained after a phase encoding step of an MR data acquisition operation having a readout period during which a phase encoding gradient and a frequency encoding gradient, each having a shearing portion of substantially the same shape and different strengths, are concurrently applied to an imaged subject; and
processing the plurality of signals to reconstruct a sheared image of the imaged subject and to unshear the sheared image to generate a reconstructed, unsheared image of the imaged subject.

14. The method of claim 13, wherein processing the plurality of signals comprises determining a difference and/or ratio of the strengths of the shearing portions of the phase encoding gradient and the frequency encoding gradient, correlating the determined difference to an amount of shearing, and removing the amount of shearing from the sheared image.

15. The method of claim 13, wherein the MR data acquisition operation comprises a two dimensional image acquisition.

16. The method of claim 13, wherein the MR data acquisition operation comprises a three dimensional image acquisition.

17. A non-transitory computer readable medium encoding one or more executable routines, which, when executed by a processor, cause the processor to perform acts comprising:
controlling a first gradient coil to apply a slice selection gradient perpendicular to a desired slice plane;
controlling a radiofrequency coil to apply, substantially simultaneously with the slice selection gradient, a radiofrequency wave having a bandwidth corresponding to the desired slice plane and a frequency corresponding to the frequency of protons present in the desired slice plane;
controlling a second gradient coil to apply, during an encoding period and in a first direction, a phase encoding gradient comprising a phase encoding portion and a shearing portion; and
controlling a third gradient coil to apply, during the readout period and in a second direction perpendicular to the first direction, a frequency encoding gradient comprising a portion having substantially the same shape as the shearing portion of the phase encoding gradient.

18. The computer readable medium of claim 17, wherein the first direction comprises a vertical direction and the second direction comprises a horizontal direction.

19. The computer readable medium of claim 17, wherein the portion of the frequency encoding gradient and the shearing portion of the phase encoding gradient have different amplitudes, and the difference between the different amplitudes determines a shearing amount.

20. The computer readable medium of claim 17, wherein the first direction comprises a horizontal direction and the second direction comprises a vertical direction.
